(19) United States
(12) Patent Application Publication
(10) Pub. No.: US 2025/0159852 A1
(43) Pub. Date: May 15, 2025

(54) PLASMONIC/TRANSITION METAL CARBO-CHALCOGENIDES COATING FOR A FLEXIBLE, DEEP AND MULTI-BANDS ELECTROMAGNETIC INTERFERENCE SHIELDING APPLICATION

(71) Applicant: Qatar Foundation for Education, Science and Community Development, Doha (QA)

(72) Inventors: Brahim Aïssa, Doha (QA); Alessandro Sinopoli, Doha (QA); Khaled Mahmoud, Doha (QA)

(21) Appl. No.: 18/938,963

(22) Filed: Nov. 6, 2024

Related U.S. Application Data
(60) Provisional application No. 63/548,046, filed on Nov. 10, 2023.

(51) Int. Cl. H05K 9/00

(52) U.S. Cl. CPC H05K 9/0088

(57) ABSTRACT

A composite material for electromagnetic interference shielding is provided. The composite material comprises an electrically conductive microscale films based on Transition Metal Carbo-Chalcogenides (Nb2S2C) stack layers. The stack is effective to provide a substantial electromagnetic interference (EMI) shielding. Once decorated with special metallic nanoparticles made mainly with noble metals including Au, Ag and Pd, this efficiency against the EMI is even enhanced. The disclosed technology introduces a special coating that can be applied to electronic devices and materials. This coating acts as a shield that protects these devices from different types of interference that can disrupt their signals and performance. This coating can work on devices that bend or move, and effectively blocks interference across a wide range of frequencies. As such, the disclosed technology keeps devices working smoothly even in places with a lot of electronic “noise” without restricting their flexibility or range of use.

### RELATED APPLICATIONS

The present disclosure claims priority to U.S. Provisional Patent Application 63/548,046 having a filing date of Nov. 10, 2023, the entirety of which is incorporated herein.

### BACKGROUND

Transition Metal Carbo-Chalcogenides (TMCs) are emerging as a promising class of materials with potential applications in various fields, including energy storage, catalysis, and electronics. However, their specific use for electromagnetic interference (EMI) shielding is not yet documented in the literature available up to present time.

Certain industries, such as telecommunications and aerospace, have stringent regulations regarding electromagnetic interference. Developing a reliable and versatile EMI shielding solution can help companies ensure their products meet these regulatory standards). Also, as electronic waste continues to be a concern, developing materials that can extend the lifespan of electronic devices by protecting them from EMI-related damage could have positive environmental impacts.

As such, there is a need for effective EMI shielding that is mechanically flexible and capable of protecting against interference across multiple frequency bands. Specifically, there is a need for developing a specialized coating using Plasmonic/Transition Metal Carbo-Chalcogenides to meet these requirements and potentially revolutionize EMI shielding in various industries and applications.

### SUMMARY

According to one non-limiting aspect of the present disclosure, an exemplary embodiment of a composite material for electromagnetic interference shielding, the composite material comprising an electrically conductive nanoscale film including transition metal carbo-chalcogenides stack layers.

Additional features and advantages are described in, and will be apparent from, the following Detailed Description and the Figures. The features and advantages described herein are not all-inclusive and, in particular, many additional features and advantages will be apparent to one of ordinary skill in the art in view of the figures and description. In addition, any particular embodiment does not have to have all of the advantages listed herein and it is expressly contemplated to claim individual advantageous embodiments separately. Moreover, it should be noted that the language used in the specification has been selected principally for readability and instructional purposes, and not to limit the scope of the inventive subject matter.

### BRIEF DESCRIPTION OF THE FIGURES

The patent or application file contains at least one drawing executed in color. Copies of this patent or patent application publication with color drawing(s) will be provided by the Office upon request and payment of the necessary fec.

FIG. 1 shows (a) XRD pattern, (b) Typical TEM image and (c) corresponding elemental analysis for Ag@Nb2S2C, according to an example embodiment of the present disclosure.

FIG. 2 shows XPS spectra of Ag—Nb2S2C: Nb 3d, Ag 3d, C 1s, S 2p, O 1s, according to an example embodiment of the present disclosure.

FIG. 3 shows (a) XRD pattern, (b) Typical TEM image and (c) corresponding elemental analysis for Au@Nb2S2C, according to an example embodiment of the present disclosure.

FIG. 4 shows XPS spectra of Au—Nb2S2C: Nb 3d, Au 4f, C Is, S 2p, O 1s, according to an example embodiment of the present disclosure.

FIG. 5 shows (a) TEM image for Pd—Nb2S2C (left) and (b) corresponding elemental analysis, according to an example embodiment of the present disclosure.

FIG. 6 shows XPS spectra of Pd—Nb2S2C: Nb 3d, Pd 3d, C 1s, S 2p, O 1s, according to an example embodiment of the present disclosure.

FIG. 7 shows a schematic of the waveguide technology employed to measure the EMA characteristics, according to an example embodiment of the present disclosure.

FIG. 8 shows a typical example of EMS (S21, in dB) measured in the millimeter-wave band for pristine Tmcc, and Tmcc decorated with Pt, Au and Ag nanoparticles: (a) 8-12 GHz, (b) 60-80 GHz, according to an example embodiment of the present disclosure.

FIG. 9 shows an evaluation of the reliability of the specimen through repeated mechanical bending tests where: (a) bent cylinder whose radius of curvature is proportional to the bending angle, (b) The variation of the electrical conductivity and EMA (i.e. electromagnetic absorption, EMA) (S21, in dB) as a function of the curvature radius, for (c) X-band and (d) M-band Frequency ranges showing a fluctuation within 10% only, according to an example embodiment of the present disclosure.

### DETAILED DESCRIPTION

The present disclosure generally relates to a composite material for electromagnetic interference shielding. The composite material comprises an electrically conductive nanoscale films based on Transition Metal Carbo-Chalcogenides (Nb2S2C) stack layers. The stack is effective to provide a substantial electromagnetic interference (EMI) shielding. Once decorated with special metallic nanoparticles made mainly with noble metals including Au, Ag and Pd, this efficiency against the EMI is enhanced.

The disclosed technology is a composite material for electromagnetic interference shielding is provided. The composite material comprises an electrically conductive nanoscale films based on Transition Metal Carbo-Chalcogenides (Nb2S2C) stack layers. The stack is effective to provide a substantial electromagnetic interference (EMI) shielding. Once decorated with special metallic nanoparticles made mainly with noble metals including Au, Ag and Pd, this efficiency against the EMI is even enhanced. The disclosed technology introduces a special coating that can be applied to electronic devices and materials. This coating acts as a shield that protects these devices from different types of interference that can disrupt their signals and performance. This coating can work on devices that bend or move, and effectively blocks interference across a wide range of frequencies. As such, the disclosed technology keeps devices working smoothly even in places with a lot of electronic “noise” without restricting their flexibility or range of use.

Moreover, the disclosed technology of a Plasmonic/Transition Metal Carbo-Chalcogenides coating for a flexible, deep, and multi-band electromagnetic interference (EMI) shielding applications addresses the critical challenge of effectively mitigating electromagnetic interference in a versatile and adaptable manner. Traditional EMI shielding materials often struggle to provide comprehensive protection across a wide range of frequencies, especially to be able to gather a deep EMI both in low and high frequency ranges, in addition to be mechanically flexible (i.e. to be adapted to complex electronic circuit).

The disclosed technology combines, for the first time, plasmonic materials with transition metal carbo-chalcogenides (namely Tmcc) to create a hybrid composite that excels in shielding against EMI (i.e. electromagnetic shielding, EMS). The Tmcc itself shows an excellent EMS value that is tangibly enhanced with the integration of plasmonic materials. Indeed, the plasmonic components are known to enable the absorption and dissipation of electromagnetic waves, while the transition metal carbo-chalcogenides offer tunable conductivity and exceptional mechanical flexibility. This dynamic combination ensures robust shielding across diverse frequency bands (here X (8-12 GHz) and M (60-80 GHz) bands).

By focusing on these three key performance goals, namely mechanical flexibility, EMS' depth, and multi-band frequency' coverage, in addition to use Tmcc decorated with plasmonic nanoparticle for the first time, the disclosed technology caters to the escalating demand for EMI protection in modern electronic devices and communication systems. It paves the way for seamless integration into various form factors, including bendable electronics and wearable devices, without compromising performance. Ultimately, the disclosed technology provides a comprehensive solution to the intricate challenge of EMI interference, fostering the advancement of electronics in an increasingly interconnected world.

### Experimental Study of the Disclosed Technology

Below are outlined example fabrication of Tmcc/Metal Nanoparticles.

| | |
|---|---|
| Ag-Nb2S2C | To start the process, 50 mg of Transition Metal Carbo- |
| | Chalcogenides (Tmcc) was dissolved in 50 mL of |
| | deionized (DI) water and subjected to stirring and |
| | probe sonication for 5 and 10 minutes, respectively. |
| | Following that, 19.7 mg of AgNO3 was introduced into |
| | the solution, and stirring and probe sonication were |
| | carried out for 5 and 10 minutes. |
| | The resulting mixture was then transferred into a 100 mL |
| | Teflon container and heated to 160° C. over 12 hours, |
| | with a gradual heat ramp-up of 2° C. per minute. |
| | After the heating process, the mixture underwent |
| | centrifugation at 2000 RCF for 5 minutes, followed by |
| | washing, and subsequently freeze-dried for 48 hours. |
| Au-Nb2S2C | To start the process, 50 mg of Transition Metal Carbo- |
| | Chalcogenides (Tmcc) was dissolved in 50 mL of |
| | deionized (DI) water and subjected to stirring and |
| | probe sonication for 5 and 10 minutes, respectively. |
| | Following that, 19.7 mg of HAuC14•3H2O was |
| | introduced into the solution, and stirring and probe |
| | sonication were carried out for 5 and 10 minutes. |
| | The resulting mixture was then transferred into a |
| | 100 mL Teflon container and heated to 160° C. over |
| | 12 hours, with a gradual heat ramp-up of 2° C. per |
| | minute. |
| | After the heating process, the mixture underwent |
| | centrifugation at 2000 RCF for 5 minutes, followed |
| | by washing, and subsequently freeze-dried for 48 hours. |
| Pd-Nb2S2C | To start the process, 50 mg of Transition Metal Carbo- |
| | Chalcogenides (Tmcc) was dissolved in 50 mL of |
| | deionized (DI) water and subjected to stirring and |
| | probe sonication for 5 and 10 minutes, respectively. |
| | Following that, 19.7 mg of Pd(acac)2 was introduced |
| | into the solution, and stirring and probe sonication |
| | were carried out for 5 and 10 minutes. |
| | The resulting mixture was then transferred into a 100 |
| | mL Teflon container and heated to 160° C. over 12 |
| | hours, with a gradual heat ramp-up of 2° C. per minute. |
| | After the heating process, the mixture underwent |
| | centrifugation at 2000 RCF for 5 minutes, followed |
| | by washing, and subsequently freeze-dried for 48 hours. |

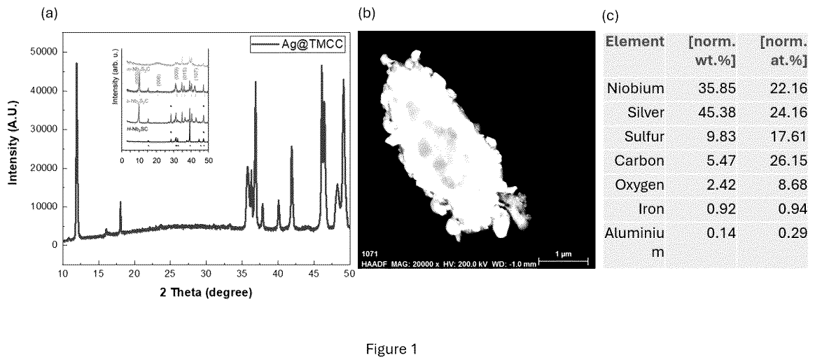

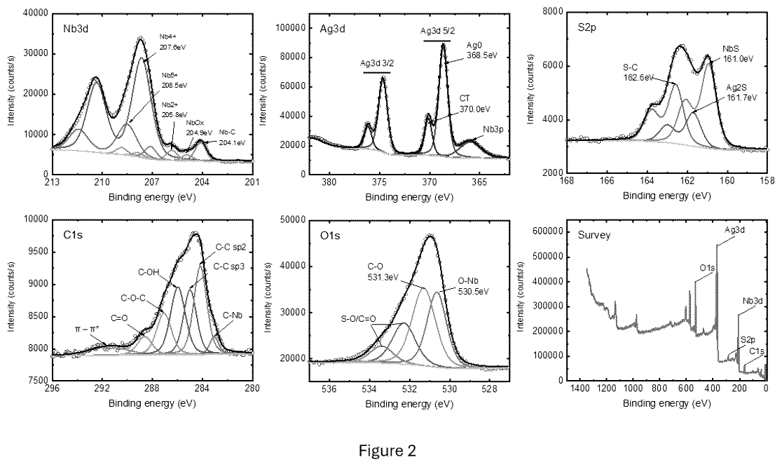

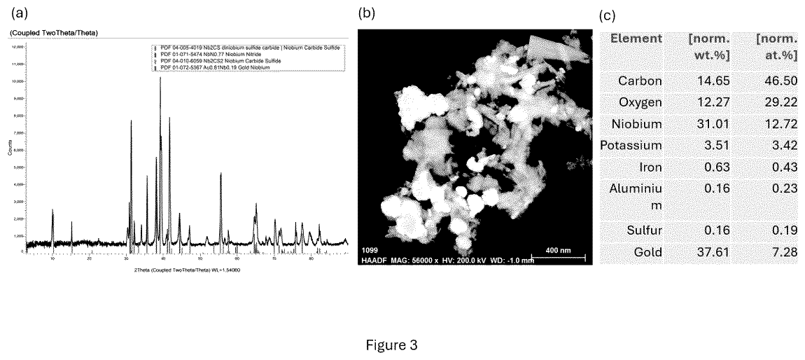

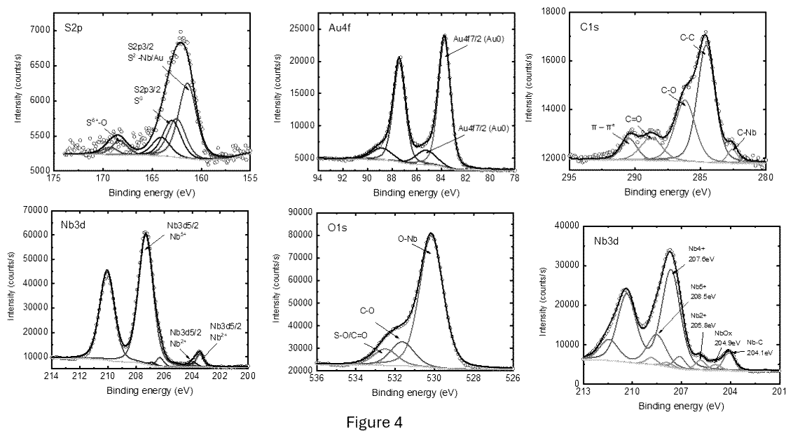

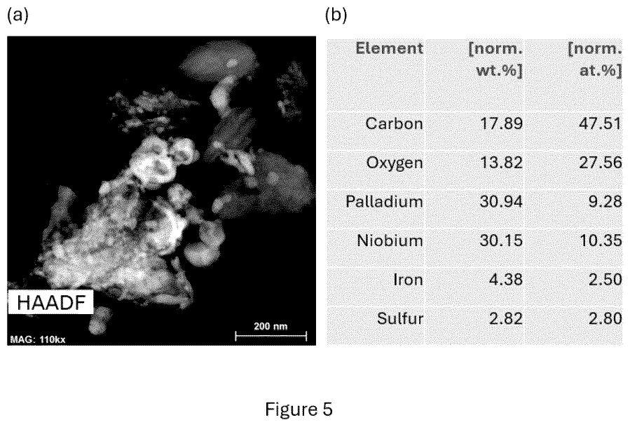

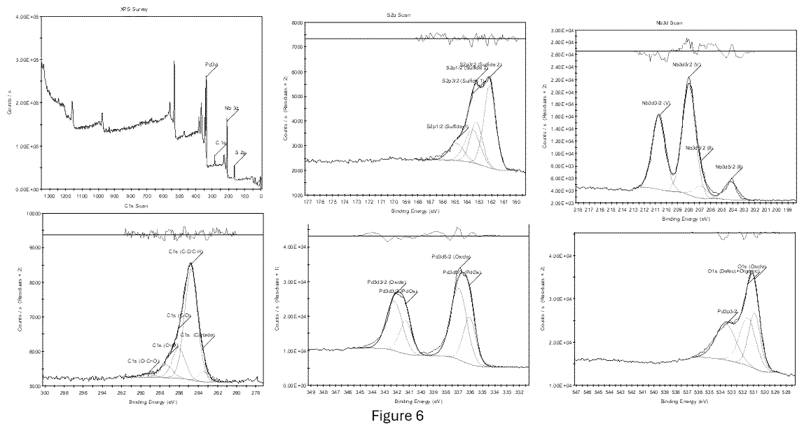

As to the above-mentioned fabrication steps: FIG. 1 shows (a) XRD pattern, (b) Typical TEM image and (c) corresponding elemental analysis for Ag@Nb2S2C; FIG. 2 shows XPS spectra of Ag—Nb2S2C: Nb 3d, Ag 3d, C Is, S 2p, O 1s; FIG. 3 shows (a) XRD pattern, (b) Typical TEM image and (c) corresponding elemental analysis for Au@Nb2S2C; FIG. 4 shows XPS spectra of Au—Nb2S2C: Nb 3d, Au 4f, C Is, S 2p, O 1s; FIG. 5 shows (a) TEM image for Pd—Nb2S2C (left) and (b) corresponding elemental analysis; and FIG. 6 shows XPS spectra of Pd—Nb2S2C: Nb 3d, Pd 3d, C Is, S 2p, O 1s.

Relatedly, as part of the disclosed technology, Electromagnetic Shielding Absorption (ESA) Measurements were taken. In order to perform ESA measurement, all the samples (Nb2S2C, Ag—Nb2S2C, Au—Nb2S2C, and Pd—Nb2S2C) were deposited as thin films on membranes. Specifically, 30 mg of each material were dispersed in 15 mL of DW. The resulting dispersions were filtered under vacuum on polyvinylidene difluoride PVDF membrane filters. The resulting films were dried in air. Typical film thickness was around 100 μm.

In the prepared materials, metal (Au, Pd, and Ag) nanoparticles (NPs) were introduced onto the Tmcc surface using a self-reduction strategy to obtain the corresponding Ag@Tmcc, Au@Tmcc, and Pd@Tmcc. This method is green and environmentally friendly because the self-reduction properties of Tmcc enable the formation of noble metal NPs with uniform sizes and controlled densities to be introduced without using reducing agents or surfactants. Such a synthetic approach has been previously adopted for decorating MXene materials with metal nanoparticles, however no previous reports have observed the self-reduction of metal nanoparticles on NbS2C2 substrates.

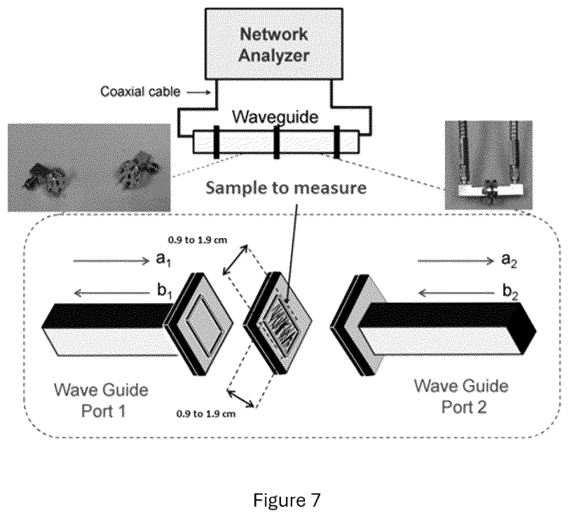

FIG. 7 shows a schematic of the waveguide technology employed to measure the EMA characteristics. The ESA (i.e. electromagnetic shielding absorbance, ESA) properties of the plasmonic/Tmcc nanocomposite films were characterized in two SHF bands, ranging from 8 to 12 GHz (X-band) and from 60 to 80 GHz, by using the waveguide method. Note that ESA, EMS and S21 mean the same value in this document, namely the electromagnetic shielding capacity of the material. To measure the scattering parameters, an Anritsu VectorStar MS4647B network analyzer was used. Prior to performing transition parameter measurements, the network analyzer was calibrated by means of standard loads kit (HPAPC-7). Unless stated otherwise, electromagnetic interference shielding (EMS), electromagnetic shielding attenuation (ESA) and electromagnetic attenuation (EMA) indicate the same notion in this disclosure.

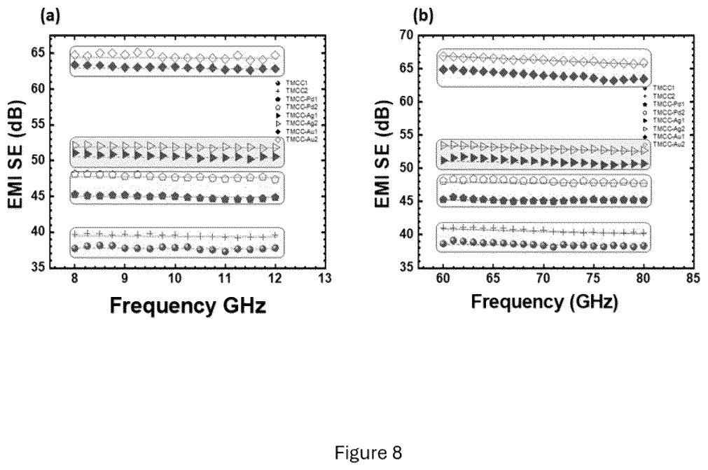

FIG. 8 shows a typical example of EMS (S21, in dB) measured in the millimeter-wave band (i.e. from 8 to 80 GHz) for pristine Tmcc, and Tmcc decorated with Pt, Au and Ag nanoparticles: (a) 8-12 GHz, (b) 60-80 GHz. These plasmonic/Tmcc nanocomposite films were then studied as EMS. The fundamental target of the EM shielding is to establish a barrier to abate the radiated electromagnetic wave either by absorption (S₂₁) or reflection (S₁₁) or by the combination of S₂₁ and S₁₁. EMA is the measure of electromagnetic energy attenuation for a given material. The EMA is determined by the power ratio of the incident and transmitted EM energy as given by: EM_{abs}=10 log P_{I}/P_{T}=20 log E_{I}/E_{T}.
where P_{I}(E_{I}) and P_{T}(E_{T}) are the power of the incident and transmitted EM radiation, respectively. E_{I} and E_{T} are the incident and transmitted intensities of the electromagnetic radiation. The unit of the EM shielding is decibel (dB). Table 1 shows the relationship between the EM absorption S₂₁ (in dB) and EMA efficiency in %.

TABLE 1
Relationship between EM absorbance effectiveness
(S21 (DB)) and Em absorbance efficiency (%).

| EM absorbance S21 (dB) | EM absorbance S21 efficiency (%) |
|---|---|
| 0 | 0 |
| 10 | 90 |
| 20 | 99 |
| 40 | 99.99 |
| 70 | 99.99999 |

The appropriate frequency band-pass (FBP) of the operating system was first defined by measuring the reflection coefficient (S₁₁) of the reference samples prior to EM attenuation measurements. These reference samples consist of: (i) the waveguide, (ii) the naked membrane substrate, and (iii) plasmonic/Tmcc nanocomposite films materials. In the X-band frequency range of 8-12 GHz, a deep EM-attenuation with a scattering parameter (S21) reaching |39| dB is measured for pristine Tmcc. In EM absorption, it is known that electric dipoles are heavy absorbers of EM energy. EM-attenuation as high as 47 decibels was measured when the Tmcc samples were doped with Palladium. This EMS reaches 51.5 dB when integrating silver nanoparticles and 64 dB when doped with gold.

Similar values were recorded in the M-band frequency, with |40| dB is measured for pristine Tmcc, |47| dB when doped with Pd, |53| dB when doped with Ag and |66| dB when doped with Au. All these EMS values were normalized to the thickness films.

It was found that once the full electrical percolation of the Tmcc film is reached (for a typical thickness of 100 μm), both Ode and EMS tend to saturate and this dependence becomes negligible. Additionally, the reliability of the specimen was probed by repeated mechanical bending tests. The plasmonic/Tmcc nanocomposite films specimens were placed into a bent cylinder whose radius of curvature is proportional to the bending angle. After bending 100 times, samples were machined to appropriate dimensions and the electrical and EM absorption was systematically measured in the two frequency bands.

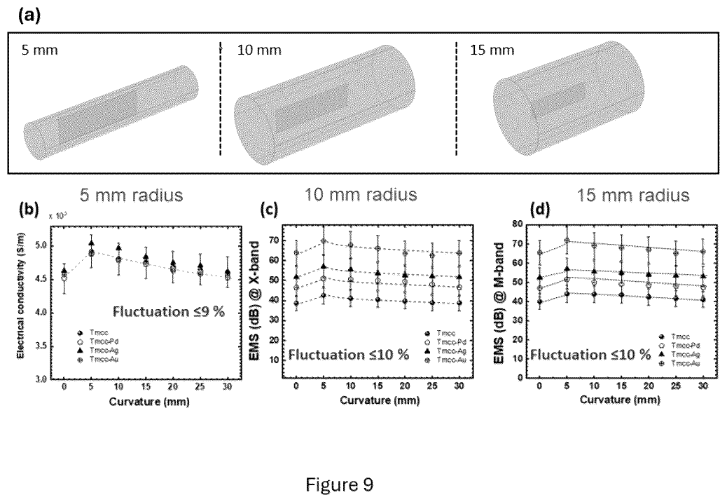

FIG. 9 shows the variation of the absorption coefficient and electrical conductivity as a function of the curvature radius. As expected, because the EMA is primarily determined by the electrical properties of the medium, no significant change was perceived and the fluctuation stayed within 10% only. The specimens show a high degree of mechanical flexibility and preserve a stable absorbance capacity as well as unvaried electrical conductivity (within the experimental uncertainties) even after being bent over 100 times.

Additionally, the disclosed technology provides multiple key advantages as outlined below.

Versatile Multi-Band Shielding: The disclosed technology offers superior EMI shielding across a wide spectrum of frequencies, surpassing existing solutions that often focus on specific frequency ranges. This versatility ensures comprehensive protection against diverse interference sources.

Mechanical Flexibility: Unlike many conventional EMI shielding materials that can be rigid and restrictive, the Disclosed technology maintains its shielding effectiveness even on mechanically flexible surfaces. This feature is essential for modern devices like flexible electronics and wearables.

Deep Shielding Penetration: The innovative plasmonic and transition metal carbo-chalcogenides combination enables deep EM shielding effect. This is a significant advantage over traditional materials that may only provide surface-level protection.

Adaptability to Varied Environments: The disclosed technology's adaptability to different environments, including extreme temperatures and varying humidity levels, ensures consistent shielding performance in a range of conditions. Existing solutions may struggle to maintain effectiveness in diverse settings.

Enhanced Device Lifespan: By minimizing electromagnetic interference, the disclosed technology helps extend the lifespan of electronic devices. This longevity advantage is particularly appealing to manufacturers and consumers seeking reliable and durable products.

Integration with Existing Manufacturing Processes: The disclosed technology's compatibility with existing manufacturing techniques allows for seamless integration into current production lines, reducing the need for costly equipment overhauls and expediting the adoption of this advanced shielding solution.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A composite material for electromagnetic interference shielding, the composite material comprising an electrically conductive microscale film including transition metal carbo-chalcogenides stack layers.

2. The composite material for electromagnetic interference shielding from claim 1, wherein the composite material for electromagnetic interference shielding further includes a noble metal.

3. The composite material for electromagnetic interference shielding from claim 2, wherein the noble metal is Au.

4. The composite material for electromagnetic interference shielding from claim 2, wherein the noble metal is Ag.

5. The composite material for electromagnetic interference shielding from claim 2, wherein the noble metal is Pb.

6. A method of creating a composite material comprising an electrically conductive nanoscale film including transition metal carbo-chalcogenides stack layers, the method comprising:
dissolving a Transition Metal Carbo-Chalcogenides (TMCC) in deionized (DI) water to result in a solution;
stirring the solution;
applying probe sonification to the solution;
adding a material to the solution to result in a mixture;
stirring the mixture;
applying probe sonification to the mixture;
transferring the mixture to a container;
heating the mixture;
centrifugating the mixture;
washing the mixture; and
freeze drying the mixture.

7. The method of claim 6, wherein 50 mg of TMCC are dissolved in 50 mL of DI water.

8. The method of claim 6, wherein the solution is stirred for 5 minutes and the probe sonification is applied for 10 minutes.

9. The method of claim 6, wherein the material is 19.7 mg of one of AgNO3, HAuCl4.3H2O, or Pd(acac) 2.

10. The method of claim 6, wherein the mixture is stirred for 5 minutes and the probe sonification is applied for 10 minutes.

11. The method of claim 6, wherein the container is a 100 mL Teflon container.

12. The method of claim 6, wherein the mixture is heated to 160° C.

13. The method of claim 12, wherein the mixture is heated with a gradual heat ramp-up of 2° C. per minute.

14. The method of claim 13, wherein the mixture is heated over 12 hours.

15. The method of claim 6, wherein the mixture is centrifugated at 2000 RCF.

16. The method of claim 6, wherein the mixture is centrifugated for 5 minutes.

17. The method of claim 6, wherein the mixture is freeze-dried for 48 hours.
